(19) United States
(12) Patent Application Publication
(10) Pub. No.: US 2006/0037778 A1
(43) Pub. Date: Feb. 23, 2006

(54) Circuit board with SMD-components and at least one wired component, and a method for populating, securing and electrical contacting of the components

(75) Inventors: Dietmar Birgel, Schopfheim (DE); Karl-Peter Hauptvogel, Bartenheim (FR)

Correspondence Address: BACON & THOMAS, PLLC, 625 SLATERS LANE, FOURTH FLOOR, ALEXANDRIA, VA, 22314, US

(73) Assignee: Endress + Hauser GmbH + Co. KG, Maulburg (DE)

(21) Appl. No.: 11/195,600

(22) Filed: Aug. 3, 2005

Related U.S. Application Data
(60) Provisional application No. 60/598,538, filed on Aug. 4, 2004.

(30) Foreign Application Priority Data
Aug. 3, 2004 (DE) 102004037786.3

(51) Int. Cl. H05K 1/11

(52) U.S. Cl. 174/260; 174/263; 174/264

(57) ABSTRACT

A circuit board and method for populating, securing and electrical contacting of components thereon is provided, as an alternative to the known pressfit technology. After the soldering of SMD-components on a first side of a circuit board, conductive adhesive and solder paste are applied on a second side of the circuit board and a connection pin of a thermally critical THT-component is inserted into the special connection bore from the first side of the circuit board. Then, on the second side of the circuit board, SMD-components are set into the solder paste. In a reflow soldering oven, the SMD components are soldered and the conductive adhesive is dried and cured. By the binding effect of a metallizing sleeve of the connection bore, the insertion of the connection pin in the area of the a constriction produces a kind of cold weld connection, which, alongside the electrical connection by the conductive adhesive, represents a redundant connection, which accompanies the highly secure mechanical connection by the conductive adhesive.

The invention relates to a circuit board with SMD-components and at least one wired component, and a method for populating, securing and electrical contacting of the components.

Besides the known soldering technique for connecting electrical and electronic components by soldering on, and to, a circuit board, the so-called pressfit technique is also used in certain cases. Such pressfit connections concern, in a narrower sense, the pressing of a so-called pressfit post, comparable to a connection pin, of a wired component into a through-contacted circuit board hole. A special feature, in this connection, is that the pressfit post has an outer diameter which is greater than the inner diameter of the through-contacted hole. Through the usually very force-intensive pressing of the pressfit post into the circuit board hole, conditions for plastic deformation are reached, which is accommodated either by a deformation of the circuit board hole or by deformation of the pressfit post. The earliest structures of the pressfit technique still used today were, and are, pressfit pins, such as e.g. contact pins and solder nails.

Encompassed by the term “wired component” herein are all components having at least one connection pin or connection wire. Wired components of this kind thus include, for example, plug pins, plug connectors, litz wire, and jumpers, but also resistors, transformers, etc. Because the connection pins or wires of such wired components are usually stuck through circuit board holes and soldered on the opposite side of the board, they are also referred to as THT-components (Through-Hole-Technique). In the following, the term “THT-component” is used as meaning the same as “wired component”.

The cited pressfit technique is used where, without melting, a gas-tight, corrosion-resistant, and mechanically robust connection is desired on the circuit board. On the other hand, the pressfit technique is also used in the case of mix-populated circuit boards, where many components in the form of SMD-parts are soldered in a reflow soldering oven, but where, however, still other, wired components are additionally to be placed on the circuit board. Such wired components, for example plug connectors, are frequently not available in the form of SMD-parts, or they are considered to be thermally critical at the solder temperatures typically found in reflow soldering ovens. High temperature resistant embodiments of such wired components are very expensive.

The pressfit technique is also used where, in the case of highly complex circuit boards populated with very sensitive components, it is not possible to solder wired components, for instance external connectors, on the circuit board. The thermal loadings of the circuit board produced in such a procedure could destroy the sensitive components, or their solder connections, already present on the circuit board. So, the relevant wired components are pressed into the circuit board in an extra step following the soldering in the reflow soldering oven, and, indeed, with the exertion of considerable force. To this end, it is necessary to provide a special pressfit tool matched to the particular components to be pressed into position. The circuit board holes, into which the connection pins, respectively pressfit posts, of the relevant, wired components are to be pressed, must, as is also the case for the pressfit posts, be metallized in a special way. Because of the high pressfit forces, it is necessary to support the circuit board carefully during the pressing.

As is evident from these considerations, a manufacture of the circuit board tailored to the requirements of the pressfit technique with reference to hole construction and material of the circuit board are just as important for a good pressfit connection as are the pressfit zone, respectively pressfit posts of the wired component itself.

While the pressfit technique has advantages, such as, for example:
no flux residues on the circuit board, to degrade the contact safety of the plug connector;
no subsequent cleaning of the circuit board required;
no additional securement of the plug connector needed; and
highly loadable connections, also with respect to high currents;
   there are also disadvantages, such as, by way of example:
expensive components for the pressfitting;
special circuit boards;
special holding, respectively supporting, of the circuit board during the pressing;
special pressfit tool; and
separate method step needed after the soldering of the other components.

An object of the invention, therefore, is to provide for otherwise usual applications of the pressfit technique a circuit board and a method for populating, securing and electrical contacting of components, which, without the use of pressfitting, offer the above-listed advantages of the pressfit technique, while simultaneously avoiding the disadvantages.

This object is achieved according to the invention by a circuit board with SMD-components and with a plurality of connection bores for the reception of connection pins, or wires, of at least one wired, electric or electronic component, with the connection bores each being formed of at least two bores, which intersect such that a constriction is formed in each connection bore in an overlap region of the bores, and that the connection pins, respectively wires, are securable in the connection bores by a conductive adhesive.

In yet another special form of embodiment of the invention, the circuit board with conductive adhesive and populated with the relevant, wired component is placed in an oven for drying or curing of the conductive adhesive.

In another embodiment of the invention, a circuit board bearing conductive adhesive and the associated, wired component is transported in such a manner through a reflow soldering oven for the drying of the conductive adhesive during a soldering procedure for the SMD-components, that the circuit board shields, or protects, the wired component from the heat required for the soldering.

The above-stated object is also achieved according to the invention by a circuit board with SMD-components and with a plurality of metallized connection bores for the reception of connection pins, or wires, of at least one wired, electric, or electronic, component, wherein the connection bores are metallized and each formed of at least two bores, which intersect, such that a constriction is formed in each connection bore in an overlap region of the bores, wherein the connection pins, or wires, are securable in the connection bores by an adhesive and electrically contactable in the region of the constrictions of the connection bores.

Another special form of embodiment of the invention provides that the circuit board with adhesive and the associated, wired component is placed in an oven for the drying, or curing, of the conductive adhesive.

Still another embodiment of a circuit board with adhesive and populated with the relevant, wired component is transported through a reflow oven for drying the conductive adhesive during a soldering procedure for the SMD-components in such a way that the circuit board shields the wired component from the heat required for the soldering.

In a special form of embodiment of the circuit board of the invention, the two bores forming a connection bore are oppositely directed, blind bores.

In another special form of the circuit board of the invention, the two bores forming a connection bore are mutually parallel, traversing bores.

The above-described object is achieved, moreover, by a method for the populating, securing and electrical contacting of electrical and electronic components on a circuit board, with the following method steps:
producing in the circuit board a plurality of connection bores for the reception of connection pins, or wires, of at least one, wired, electric, or electronic, component from, in each case, at least two bores, which intersect in such a way that a constriction is formed in each connection bore in an overlap region of the at least two bores;
applying solder paste on solder pads and adhesive on, and/or in, the connection bores for the wired, electric, or electronic, component on one side of the circuit board;
populating SMD-components on the solder pads and inserting the connection pins, or connection wires, of the wired component into the connection bores;
soldering the solder paste and drying the conductive adhesive in a reflow soldering oven.

In a special embodiment of this method of the invention, in the case of a thermally critical, wired component, such is populated on the side of the circuit board lying opposite to the SMD-components, before the already populated circuit board is charged into the reflow soldering oven and wherein the circuit board shields the wired component during passage through the reflow soldering oven from the heat required for the soldering.

Another variant of the method of the invention for the two-sided populating, securing and electrical contacting of electrical and electronic components on a circuit board includes the following method steps:
producing in the circuit board a plurality of connection bores for the reception of connection pins, or wires, of at least one, wired, electric, or electronic, component from, in each case, at least two bores, which intersect in such a way that a constriction is formed in each connection bore in an overlap region of the at least two bores;
applying conductive adhesive onto and/or into the connection bores for the wired electric, or electronic, component on a second side of the circuit board;
inserting the connection pins, or wires, of the wired component into the connection bores;
applying solder paste on solder pads on a first side of the circuit board;
populating SMD-components onto the solder pads of the first side of the circuit board; and
soldering the solder paste and drying the conductive adhesive in a reflow soldering oven, wherein the circuit board shields the wired component from the heat required for the soldering during the travel through the reflow soldering oven.

Yet another variant of the method of the invention for the two-sided populating, securing and electrical contacting of electrical and electronic components on a circuit board, relates to the following method steps:
producing in the circuit board a plurality of connection bores for the reception of connection pins, or wires, of at least one, wired, electric, or electronic, component from, in each case, at least two bores, which intersect in such a way that a constriction is formed in each connection bore in an overlap region of the at least two bores;
applying solder paste on solder pads on a first side of the circuit board;
populating SMD-components onto the solder pads on the first side of the circuit board;
soldering the first side of the circuit board in a reflow oven;
applying solder paste on solder pads and applying conductive adhesive onto and/or into the connection bores for the wired, electric, or electronic, components on a second side of the circuit board;
inserting the connection pins, or wires, of the wired component into the connection bores;
populating SMD-components on the solder pads on the second side of the circuit board;
soldering the solder paste and drying the conductive adhesive in a reflow oven.

In an special embodiment of this method, in the case of a thermally critical, wired component, the connection pins, or wires, of the wired component are inserted from the first side of the circuit board, into the connection bores, following the application of conductive adhesive onto the second side of the circuit board, and the circuit board is transported through the reflow soldering oven in such a manner that it shields the wired component from the heat required for the soldering.

Again another variant of the method of the invention for the two-sided populating, securing and electrical contacting of electric and electronic components on a circuit board includes the following method steps:
producing in the circuit board a plurality of connection bores for the reception of connection pins, or wires, of at least one, wired, electric, or electronic, component from, in each case, at least two bores, which intersect in such a way that a constriction is formed in each connection bore in an overlap region of the at least two bores;
applying solder paste on solder pads on a first side of the circuit board;
populating SMD-components onto the solder pads;
soldering the solder paste and the SMD-components on the first side of the circuit board in a reflow soldering oven;
inserting the connection pins, or wires, of the wired component into the connection bores;
applying solder paste onto solder pads and conductive adhesive onto and/or into the connection bores for the wired, electric, or electronic, component on a second side of the circuit board;
populating SMD-components onto the solder pads of the second side of the circuit board;
soldering the solder paste and the SMD-components of the second side of the circuit board and drying the conductive adhesive in a reflow soldering oven, wherein the circuit board shields the wired component against the heat required for the soldering during the passage through the reflow oven.

Still another variant of the method of the invention for the two-sided populating, securing and electrical contacting of SMD-components and plural, wired components, of which at least one is a thermally critical, wired component, on a circuit board concerns the following method steps:
producing in the circuit board a plurality of connection bores for the reception of connection pins, or wires, of at least one, wired, electric, or electronic, component from, in each case, at least two bores, which intersect in such a way that a constriction is formed in each connection bore in an overlap region of the at least two bores;
applying solder paste on solder pads on a first side of the circuit board;
populating SMD-components on the solder pads;
soldering the first side of the circuit board in a reflow oven;
applying adhesive onto a second side of the circuit board for the securing of SMD-components;
populating the second side of the circuit board with SMD-components;
populating the one or more wired and thermally uncritical components on the first side of the circuit board;
soldering in a wave soldering installation;
applying conductive adhesive onto and/or into the connection bores for the wired, electric, or electronic, component on the second side of the circuit board;
inserting the connection pins, or wires, of the thermally critical, wired component into the connection bores;
curing the conductive adhesive.

A special embodiment of this method of the invention concerns the use of plural, wired components on the circuit board, wherein all wired components are inserted into connection holes and secured by conductive adhesive.

In the case of yet another embodiment of the method of the invention, the connection bores for receiving connection pins, or wires, of the wired component are metallized.

In the case again of a special embodiment of the method of the invention, the connection bores for receiving connection pins, or wires, of the wired component are metallized, and, instead of the conductive adhesive, a non-conductive adhesive is used, wherein an electrical contacting of the connection pins, or wires, of the wired component is made in the region of the constrictions of the connection bores.

A particular advantage of the invention resides in its use of specially formed connection bores for the connection wires, or pins, of wired components and their securement and electrical contacting by conductive adhesive. The connection bores for the connection wires, or pins, of the wired components are so formed according to the invention that they enable a secure binding of the connection wires, or pins, with the special form also preventing the known problem with conductive adhesives of their tendency to flow out of the circuit board holes.

If the connection bores of the invention are metallized, so that they are clothed internally by metallized sleeves, then it is even not necessary to use a conductive adhesive for producing an electrically conductive connection, and, instead, a non-conductive adhesive can be used, for example an adhesive for SMD-components. Thus, these metallized connection bores utilize a binding, or seizing, effect, whereby a kind of cold-welded connection is achieved in the region of their constriction, upon the insertion of the connection pins, this result being similar to that realized in the case of pressfit technology. An electrically conductive, low-ohmic contact is produced, which complements the mechanically high-strength connection effected by the conductive adhesive. If, according to the invention, metallized connection bores and conductive adhesive are used, then the cold-welded connection between the connection wires, or pins, and the metallization sleeves of the connection bores represents an electrical connection redundant to that produced by the conductive adhesive.

The invention is suited for thermally critical and sensitive components, which usually must be soldered in a manual soldering process. These thermally critical and sensitive components can now, according to the invention, be secured and contacted on the circuit board by means of conductive adhesive or non-conductive adhesive during a soldering passage through a reflow soldering oven, with the circuit board itself shielding the sensitive components against the heat required for the soldering. It has been found that conductive adhesive can be tailored such that it can also be used for the method of the invention in the context of lead-free soldering in the reflow oven, although the circuit boards and component are then, in such case, subjected to distinctly greater temperatures in the reflow soldering oven than is the case with lead-containing solders. Following curing of the conductive adhesive, the conductive adhesive connection is resistant to high temperatures. Non-conductive adhesives, for example for the bonding of SMD-components, are already available for such temperatures as are required for lead-free solders in a reflow soldering oven. The invention is suited, moreover, for all lead-free surfaces, be it lead-free surfaces of the circuit board or of the connection pins of wired components.

As with known non-conductive adhesives, also the conductive adhesive used according to the invention can be applied onto the desired locations of the circuit board using screen printing, which can be executed by automatic equipment. An application from a dispenser is, as usual, also possible.

In general, the invention is suited for those wired components, which, because of their geometry, are otherwise not solderable in a reflow soldering oven, because they require concealed solderings, or for such components, which, because of their heat capacity, are otherwise not solderable in reflow soldering ovens, because the heat required for melting the solder can not be brought to the solder location.

The invention can replace the usual pressfit technique and prevent its disadvantages. It is, additionally, much simpler and more economical to implement, compared to the conventional pressfit technique.

The invention will now be explained and described in more detail on the basis of examples of embodiments, with reference to the accompanying drawing, the figures of which show as follows:

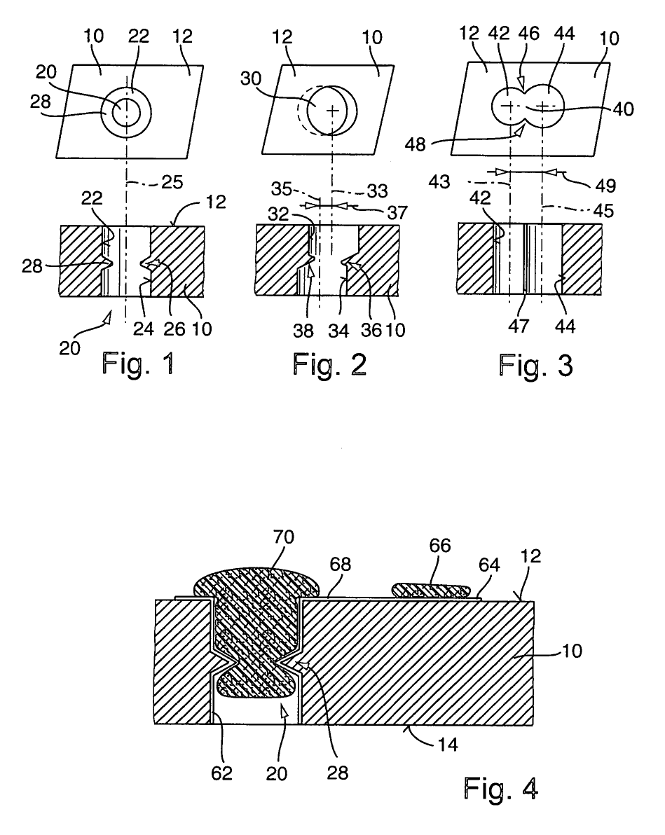

FIG. 1 a schematic presentation of a first example of an embodiment of a circuit board of the invention having a connection bore for a connection pin of a THT-component;

FIG. 2 a schematic presentation of a second example of an embodiment of a circuit board of the invention having a connection bore for a connection pin of a THT-component;

FIG. 3 a schematic presentation of a third example of an embodiment of a circuit board of the invention having a connection bore for a connection pin of a THT-component;

FIG. 4 a schematic presentation of a circuit board of FIG. 1, following the application of solder paste and conductive adhesive according to a method of the invention;

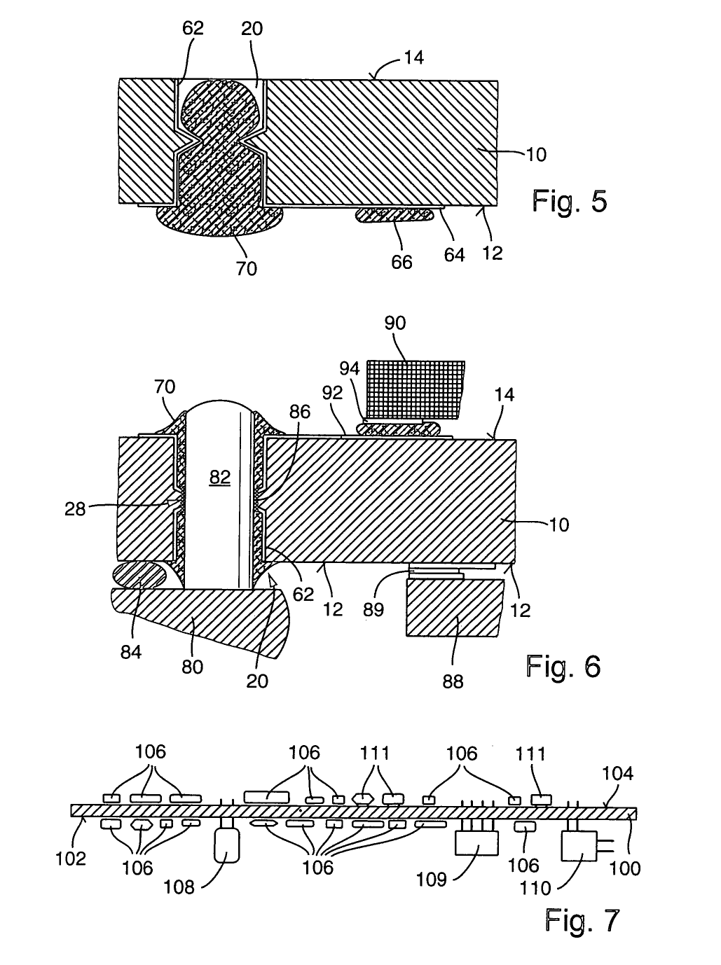

FIG. 5 a schematic presentation of a circuit board of FIG. 1, following the application of solder paste and conductive adhesive according to a further method of the invention;

FIG. 6 a schematic presentation of a part of a populated and soldered circuit board of the invention according to FIG. 1;

FIG. 7 a schematic presentation of a further embodiment of a populated and soldered circuit board of the invention;

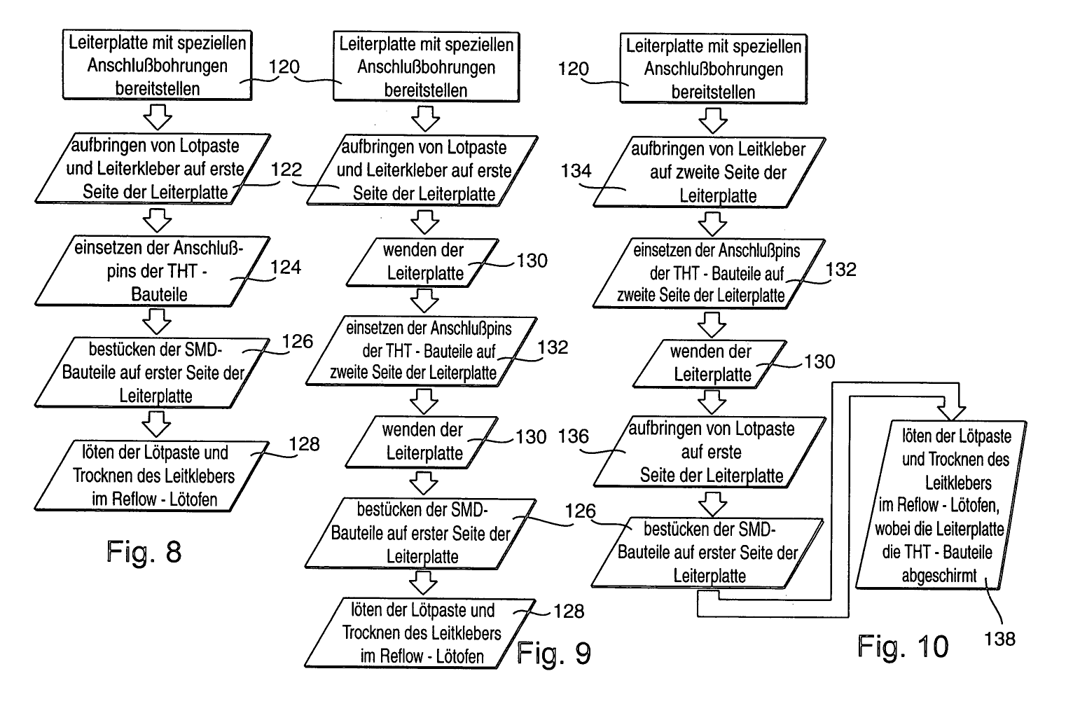

FIG. 8 a schematic presentation of an embodiment of a method of the invention for populating, securing and electrical contacting of components on a circuit board;

FIG. 9 a schematic presentation of another embodiment of a method of the invention for populating, securing and electrical contacting of components on a circuit board;

FIG. 10 a schematic presentation of a further embodiment of a method of the invention for populating, securing and electrical contacting of components onto a circuit board;

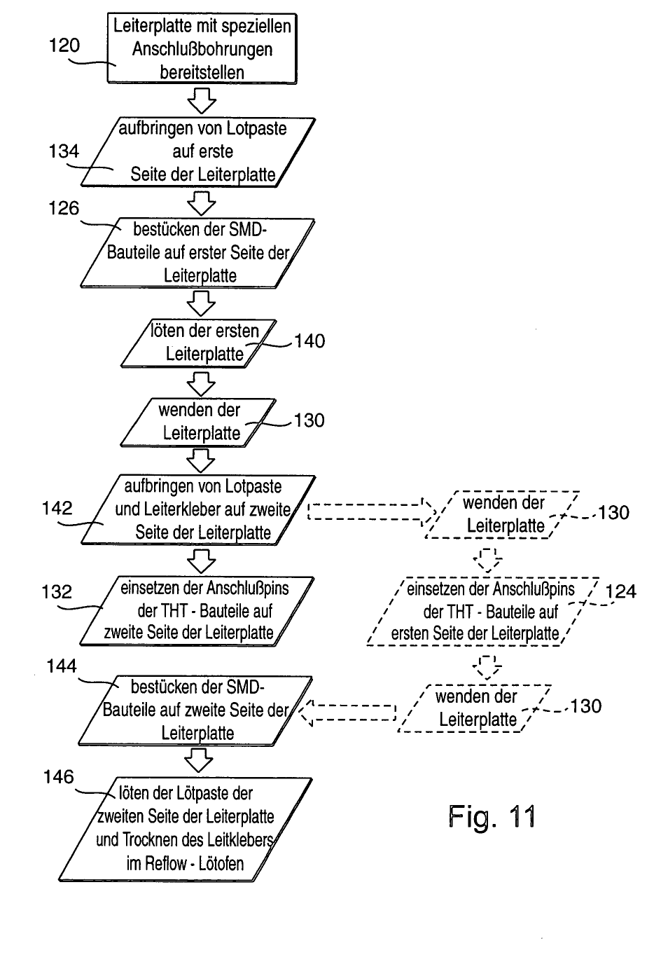

FIG. 11 a schematic presentation of still other embodiments of a method of the invention for populating, securing and electrical contacting of components on a circuit board; and

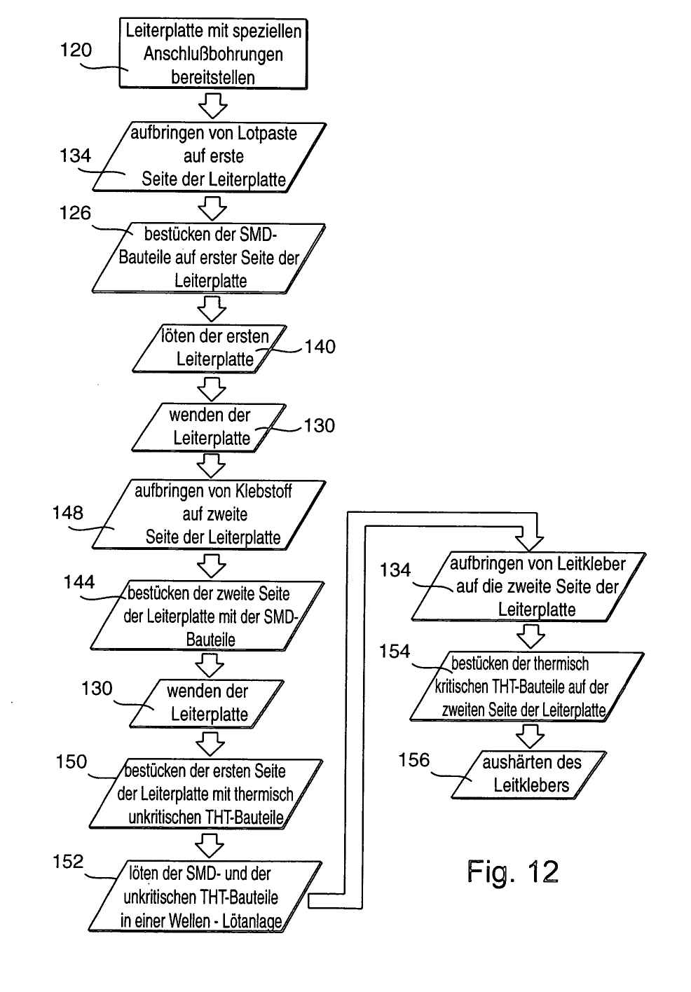

FIG. 12 a schematic presentation of yet another embodiment of a method of the invention for populating, securing and electrical contacting of components on a circuit board.

If reasonable for simplification in the drawing, equal elements, components and modules have been provided with equal reference characters.

FIG. 1 shows schematically a first example of an embodiment of a circuit board 10 according to the invention, with a connection bore 20 for a connection pin 82 of a THT-component 80 (shown in FIG. 6). For simplification and clarity, the circuit board 10 is shown as a broken-away portion thereof, as viewed onto its side 12 and in an elevational cross section. The connection bore serves for receiving and electrical contacting of connection pins, or wire, of a wired electric, or electronic, component. It is clear that such a circuit board will usually have a plurality of connection bores. For the invention, however, the actual number of connection bores is not definitive; they also need not all be formed in the same way as the connection bore shown in FIG. 1.

The connection bore 20 in the example of an embodiment of the invention illustrated here is formed from two oppositely directed, blind bores 22, 24 extending inwards from different sides of the circuit board 10 and not drilled completely through the circuit board 10, but, instead, only to just half of the circuit board thickness. At their bases, the two blind bores 22, 24 overlap, but the second blind bore 24 does not penetrate into the first blind bore 24 completely with reference to diameter. As shown in FIG. 1, this leads to the formation of a constriction 28 in the connection bore 20 in an overlap region 26 of the blind bores 22, 24. This constriction safely binds and holds securely in the connection bore 20 a connection pin, or wire, 82 of a THT-component 80 (see, in this connection, FIG. 6) inserted into the connection bore 20.

The two blind bores 22, 24 of the example of the circuit board 10 shown in FIG. 1 are essentially equal in their diameters and are aligned, as indicated by a common centerline 25. It is also conceivable that the two blind bores align but have different diameters, so that, at the transition from the bore with the greater diameter to the bore with the smaller diameter, a kind of shoulder is formed, which serves as a constriction for a connection pin, or wire, of a THT-component inserted into the connection bore. Such a shoulder would then have a similar binding action to that of the constriction 28 shown in FIG. 1.

Another example of an embodiment of the circuit board 10 of the invention is shown in FIG. 2. In this case, a connection bore 30 is, similarly to FIG. 1, formed again from two oppositely directed blind bores, here blind bores 32, 34, but, now, the blind bores 32, 34 are shifted relative to one another, this being indicated in FIG. 2 by the non-aligned center lines 33, 35. Also in the case of this example of an embodiment, the two, oppositely directed, blind holes 32, 34 are drilled from opposite sides of the circuit board 10 and not completely through the circuit board 10, but, instead, in each case only to half of the circuit board thickness. Again, at their bases, the two blind bores overlap. As shown in FIG. 2, this provides in an overlap region 36 of the blind bores 32, 34 a constriction 38 in the connection bore 30, which binds securely, and holds in the connection bore 30, a THT-component 80 connection pin, or wire, 82 (see, in this connection, FIG. 6) inserted into the connection bore 30. The binding action exerted by the constriction 38 on a connection pin, or wire, is determined by a displacement 37 of the two blind bores 32, 34.

Although the form of embodiment illustrated in FIG. 2 again shows two blind bores of equal diameter, diameters of different size are also conceivable for implementing the invention.

Yet another example of an embodiment of the circuit board 10 of the invention is illustrated in FIG. 3, again in the form of a view onto the first side 12 of the circuit board, accompanied by a corresponding, elevational, cross sectional view thereof. In the case of this form of embodiment, a connection bore 40 is, as in the case of FIGS. 1 and 2, formed from two parallel bores, here bores 42, 44. Here, the bores 42, 44 completely traverse the thickness of the circuit board, offset from one another, as is illustrated in FIG. 3 by the two parallel, non-aligned, centerlines 43, 45. Also these two bores 42, 44 overlap, in this case such that ridges 47 are formed in an overlap region 46.

These ridges protrude into the connection bore 40 and effect a constriction 48 of the passageway through the connection bore 40.

By means of these ridges 47 serving as constriction 48, an inserted connection pin, or wire, of a THT-component is, in turn, bound, or seized, securely and held in the connection bore.

The form of embodiment shown in FIG. 3 has two bores 42, 44 of different diameter. However, also equal diameters are conceivable for an implementation of the invention. In any case, the actually achievable binding effect is determined by the offset 49 of the two bores 42, 44.

As already explained above, the invention provides that connection pins, or wires, of THT-components are secured and electrically contacted in the connection bores 20, 30, 40 of FIGS. 1-3 using a conductive adhesive. FIG. 4 is a schematic, sectional presentation of a circuit board 10 with a form of embodiment of a connection bore 20, as it is also shown in FIG. 1 and which has been chosen here by way of example. Other forms of embodiment of the connection bore of the invention can also be used, instead of the connection bore 20 used here, for example, the forms of embodiment of the connection bores 30, 40 of the invention shown in FIGS. 2 and 3. The following explanations for the embodiment of the connection bore 20 shown in FIGS. 4 and 5 are, consequently, just as applicable correspondingly for the other forms of embodiment of the connection bores 30 and 40 of FIGS. 2 and 3.

FIG. 4 shows the circuit board 10 with the connection bore 20 filled by a conductive adhesive 70. In the case of the example of the circuit board 10 illustrated here, only its first side 12 is populated. Its second side remains free. Preferably, the connection bore 20 is metallized, as is illustrated in FIG. 4 by metallization sleeve 62, which is connected with a conductive trace 68 and a solder pad 64 for an SMD-component (not shown in FIG. 4; see FIG. 6). Solder paste 66 and conductive adhesive 70 were applied onto the same first side 12 of the circuit board from above, according to the orientation shown in FIG. 4, and were preferably applied by printing. The conductive adhesive 70 can, however, also be applied by means of a dispenser. FIG. 4 shows the circuit board 10 directly after the application of solder paste 66 and conductive adhesive 70 according to a method of the invention. Following insertion of a THT-component connection pin, or wire, into its intended connection bore 20 and into the conductive adhesive, the SMD-component provided for the mentioned solder pad is put in place. The completely populated circuit board 10 is then brought into a reflow soldering oven, where the SMD-component is soldered and the conductive adhesive 70 dried and cured.

To the extent that the THT-components to be mounted on the circuit board 10 are of a type which go through a soldering process in a reflow soldering oven undamaged, the circuit board 10 and the components populated on its first side 12, as described, are brought into the reflow soldering oven in the position shown in FIG. 4.

FIG. 5 shows, in contrast, the circuit board 10 of FIG. 4 with already applied solder paste 66 and conductive adhesive 70, turned upside down following their application, so that, as shown here, the first side 12 of the circuit board 10 is directed downwards. Such a position of the circuit board 10 is advantageous, according to the invention, when a connection pin, or wire, of a THT-component is inserted into the connection bore 20 and into the conductive adhesive 70, which THT-component is thermally critical and cannot go through a usual soldering process in a reflow soldering oven undamaged. In this case, with the circuit board 10 in the position shown in FIG. 5, first the connection pin, or wire, of the thermally critical THT-component is inserted from the second side of the circuit board 10 into the connection bore 20 and into the conductive adhesive 70. Following this, the circuit board 10 is turned right side up and then the SMD-component provided for the solder pad 64 is placed onto the solder paste 66. For the soldering, the circuit board 10 is transported through the reflow soldering oven with its first side up, with the circuit board 10 itself then shielding the thermally critical THT-component from the heat required for the soldering. The thermally critical THT-component can, in such a position, where it is transported through the reflow soldering oven hanging beneath the circuit board 10, withstand the soldering temperatures in the reflow soldering oven undamaged. The conductive adhesive 70 can be dried and cured in the reflow soldering oven in the same process step in which the SMD-components are soldered.

FIGS. 4 and 5 make clear the advantageous effect of the connection bore 20 of the invention. The constriction 28 prevents that the conductive adhesive 70 flows out of the connection bore following its placement therein. This is true in the same way for the other examples of connection bores 30 and 40, which are illustrated in FIGS. 2 and 3. It is, in principle, arbitrary, from which side the conductive adhesive 70 is applied to the circuit board 10.

A similar situation is illustrated in FIG. 6 using as an example a circuit board which is populated on both sides. The SMD-components populated on the first side 12 of the circuit board 20, here symbolized by a first SMD-component 88 on its solder pad 89, have already been soldered in a first soldering process in a reflow soldering oven. After the subsequent application of conductive adhesive 70 and solder paste 94 on a second solder pad 92 of the circuit board 10, here acting in a representative capacity for many other pads on a usual circuit board of this kind, the circuit board 10 is first turned over, so that a connection pin, or wire, 82 of a thermally critical THT-component 80 can be inserted from above, thus from the first side 12 of the circuit board 10, into the connection bore 20 provided with a metallization 62. If the example illustrated in FIG. 6 concerns a heavy THT-component 80, or one which can tip, then it is advantageous to place a drop of adhesive 84, preferably an adhesive such as is used for the bonding of SMD-components, on the circuit board 10, before the insertion of the THT-component into the connection bore 20. In this way, the THT-component 80 is secured, and the circuit board can then be turned over again, without the THT-component 80 falling, with its connection pin, or wire, 82, out of the connection bore 20. On the then upwardly facing, second side 14 of the circuit board 10, again in this case a representatively illustrated, second SMD-component 90 has been set into the solder paste 94 on the soldering pad 92. This is the state illustrated in FIG. 6. The circuit board 10 of the invention, populated in this way, is ready to be brought into a reflow soldering oven, where the SMD-component 90 on the second side 14 of the circuit board 10 is soldered, and the conductive adhesive 70 in the connection bore 20 is dried and cured. The circuit board 10 passes through the reflow soldering oven in this case such that the thermally critical THT-component is underneath the circuit board 10 and is, thus, shielded from the heat.

FIG. 6 makes clear also yet another, especially advantageous feature of the invention. With the special binding action, according to the invention, of the connection bore 20 (and also of the connection bores 30 and 40 of FIGS. 2 and 3), the insertion of a connection pin, or wire, of a wired component produces a kind of cold weld connection in the region of the constriction 28 between the metallization sleeve 62 and the connection pin, or wire. Besides the electrical connection produced by the conductive adhesive 70, this cold weld connection represents a redundant connection of the relevant, wired components to the circuit board, which accompanies the mechanically high-strength connection produced by the conductive adhesive.

For the sake of completeness, FIG. 7 illustrates a circuit board 100 produced according to the invention. On its first side 102, this circuit board 100 is populated with various SMD-components 106, which are preferably set on the circuit board 100 and soldered in a reflow soldering oven in a first step of the method of the invention. Following a time for cooling, solder paste and conductive adhesive are applied on the first side (see, in this connection, FIG. 6) and thermally critical THT-components, such as, for example, a load-limiting device 108, a transformer 109 and an external connector 110, are inserted into the connection bores 20, 30, 40 provided with conductive adhesive.

In case the circuit board 100 is, as in the example of an embodiment illustrated in FIG. 7, to be populated with thermally uncritical THT-components, for instance high-load, or power, resistors 111, the circuit board 100 is turned over, and the thermally uncritical power resistors are inserted from the second side into connection bores 20, 30, 40 of the invention provided previously with solder paste. Subsequently, each of the SMD-components 106 provided for the second side 104 of the circuit board 100 is set onto the appropriate, solder-paste-equipped, solder pads. Then, the circuit board 100 is brought again into the reflow soldering oven, so that the SMD-components 106 and the thermally uncritical THT-components 111 are soldered on the second side 104 of the circuit board 100. At the same time, the circuit board 100 shields the thermally critical THT-components 108, 109, 110 located underneath the circuit board 100 from the heat in the reflow soldering oven, while, at the same time, the conductive adhesive is dried and cured. Such a populated and soldered circuit board 100 is illustrated in FIG. 7.

Found to be especially advantageous for the present invention are already obtainable, special reflow ovens which additionally shield sensitive components underneath the circuit board 10 in the reflow oven by cooling from below.

FIGS. 8-13 illustrate various examples of embodiments of methods of the invention for populating, securing and electrical contacting of components on a circuit board.

Thus, in FIG. 8, a first example of an embodiment of such a method is presented, such as is used, for example, in the case of circuit boards populated on just one side with SMD-components and thermally uncritical THT-components. Following the preparing 120 of a circuit board with plural connection bores 20, 30 or 40 for receiving connection pins, or wires, of at least one wired, electric and/or electronic component, preferably of a circuit board 10 of the invention, such as such is shown in FIGS. 1-3 and described already above, there occurs an applying 122 of solder paste and conductive adhesive on a first side 12 of the circuit board 10 (see, in this connection, also FIGS. 1-3). After an inserting 124 of the connection pins of the one or more THT-components into the connection bores 20, 30 or 40, the SMD-components are populated 126 on the first side 12 of the circuit board 10, preferably in an automatic populating machine. Thereafter, a soldering 130 of the circuit board 10 is done in a reflow soldering oven, with the temperature profile of the soldering process selected such that the conductive adhesive dries and cures properly in the reflow soldering oven.

Due to the above-explained binding effect, which the constrictions 28, 38, or 48 exert in the connection bores 20, 30, or 40 on the respective connection pins of the THT-components, the connection pins must be pressed with a certain amount of force into the connection bores 20, 30 or 40. The shape of the connection bores 20, 30 or 40 determines the amount of force which must be exerted to overcome the binding effect of the constrictions 28, 38 or 48. It has been found in practice that the connection bores 20, 30 or 40 can be so shaped in simple manner, such that the amount of force required for the pressing of the connection pins into place can be obtained from conventional populating, automatic machinery. In no case is it necessary to use what would be considered a large insertion force, such as required in conventional pressfit technology.

FIG. 9 presents schematically a second example of an embodiment of a method of the invention for populating, securing and electrical contacting of electric and electronic components on a circuit board 10 of the invention (see, in this connection, FIGS. 1-3). This method is applied in the case of circuit boards populated on one side with SMD-components. The method of FIG. 9 corresponds, in principle, to the method of FIG. 8, except that here, in addition to the SMD-components on the first side 12 of the circuit board 10, there is provided at least one thermally critical THT-component, which is arranged on the second side 14 of the circuit board 10. In a soldering procedure in a reflow soldering oven, in which the SMD-components are soldered on the first side 12 of the circuit board 10, the thermally critical THT-component located beneath the circuit board is shielded by the circuit board from the impinging energy for the soldering.

In the method of FIG. 9, there occurs, following the preparing 120 of a circuit board 10 of the invention (see, in this connection, FIGS. 1-3), an applying 122 of solder paste and conductive adhesive onto the first side 12 of the circuit board 10. Following a turning 130 of the circuit board 10 and an inserting 132 of the connection pins of the one or more THT-components into the connection bores 20, 30 or 40 from the second side 14 of the circuit board 10 (see, in this connection, FIGS. 1-3), the circuit board is turned over again, this being indicated in FIG. 9 by a repeated reference character “130”. There follows, now, the populating 126 of the SMD-components on the first side 12 of the circuit board 10, preferably in an automatic populating machine. After this, the soldering 130 of the circuit board 10 occurs in a reflow soldering oven utilizing a temperature profile such that the conductive adhesive is properly dried and cured in the reflow oven. As already described above, during soldering in a reflow soldering oven, wherein the SMD-components are soldered on the first side, the thermally critical THT-component is shielded by the circuit board from the energy fed for the soldering.

Also in the case of the method shown in FIG. 9, the connection pins of the one or more THT-components are again first pressed into the special connection bores 20, 30 and 40 of the invention, before the SMD-components are populated. This measure prevents possible dislodging of the SMD-components out of the solder paste during the inserting of the connection pins.

FIG. 10 schematically depicts a third example of an embodiment of a method of the invention for populating, securing and electrically contacting components on a circuit board 10 of the invention (see, in this connection, FIGS. 1-3). Also this method is applied, as in the case of the method of FIG. 9, for circuit boards populated on one side with SMD-components, wherein also here, in addition to the SMD-components on the first side 12 of the circuit board 10, at least one thermally critical THT-component is arranged on the second side 14 of the circuit board 10. The essential difference compared to the method of FIG. 9 is that, in the method of FIG. 10, the conductive adhesive for the one or more thermally critical components is applied on the same side, here the second side 14, of the circuit board 10, from which the connection pins of the one or more THT-components are pressed into the connection bores 20, 30 or 40 (see, in this connection, also FIGS. 1-3).

In particular, in the method of FIG. 10, following preparation 120 of a circuit board 10 of the invention (see, in this connection, FIGS. 1-3), conductive adhesive is applied 134 onto the second side 14 of the circuit board 10, followed by insertion 132 of the connection pins of the one or more THT-components into the connection bores 20, 30 or 40 from the second side 14 of the circuit board. Following the turning 130 of the circuit board 10 over, solder paste is applied 136 onto the first side 12 of the circuit board 10 and this is followed by the populating 126 of the SMD-components on this side of the circuit board 10, preferably in an automatic populating machine. Thereafter, there follows again a soldering 138 of the circuit board 10 in a reflow soldering oven utilizing a temperature profile that properly dries and cures the conductive adhesive in the reflow soldering oven. As already described above, during the soldering 138, the circuit board shields the one or more thermally critical THT-components located beneath the circuit board from the energy feed required for the soldering.

While, in the case of the methods of the invention described to this point and illustrated in FIGS. 8-10, the circuit boards were only populated on one side with SMD-components, the methods of the invention shown in FIGS. 11 and 12 involve the populating of both sides of the circuit boards 10 with SMD-components, so that the boards then look similar to the circuit board shown in FIG. 7.

FIG. 11 illustrates schematically a fourth example of an embodiment of a method according to the invention, in which, first, one side of the circuit board 10 (see, in this connection, FIGS. 1-3) is provided with SMD-components and soldered, before the other side of the circuit board 10 is populated. In particular, following preparation 120 of a circuit board 10 according to the invention (see, in this connection, FIGS. 1-3), the application 134 of solder paste on the first side 12 of the circuit board 10 and the populating 126 of the SMD-components on this side of the circuit board 10, preferably in an automatic populating machine, occur. Following a soldering 140 of the SMD-components on the first side 12 of the circuit board 10 in a reflow soldering oven, the circuit board 10 is turned over 130, so that then an application 142 of solder paste and conductive adhesive on the second side 14 of the circuit board 10 can transpire. Preferably, the insertion 132 of the connection pins of the one or more THT-components into the connection bores 20, 30 or 40 is then done from the second side 14 of the circuit board 10. Thereafter, a populating 144 of the second side 14 of the circuit board 10 with SMD-components is carried out, and, indeed, preferably again in an automatic populating machine.

Following this, a soldering 146 of the circuit board 10 is obtained in a reflow soldering oven, with the temperature profile of the soldering process being chosen such that the conductive adhesive properly dries and cures in the reflow soldering oven.

In the method shown in FIG. 11 and described to this point, the one or more THT-components on the second side 14 of the circuit board 10 are subjected, along with the SMD-components on this side of the circuit board, to the heat required for the soldering. This method is used, consequently, when only thermally uncritical THT-components are present. If, however, a thermally critical THT-component is also present, then such should be populated on the first side of the circuit board 10, after the soldering 140 of the first side, so that it will be beneath the circuit board 10 and shielded by the circuit board from the energy feed required for the soldering, during the soldering 146 of the SMD-components on the second side 14 of the circuit board 10 in the reflow soldering oven. The measures occurring in this variant of the method of the invention are shown dashed in FIG. 11: Following application 142 of solder paste and conductive adhesive on the second side 14 of the circuit board 10, the circuit board 10 is turned over 130 and the insertion 124 according to FIG. 1 of the connection pins of the one or more THT-components into the connection bores 20, 30 or 40 is done from the first side 12 of the circuit board 10. Before the populating 144, already specified above, of the second side 14 of the circuit board 10 with SMD-components, the circuit board 10 is again turned over 130.

Compared to the method illustrated in FIG. 11, the further example of an embodiment of a method of the invention for populating, securing and electrical contacting of electric and electronic components on a circuit board shown in FIG. 12 exhibits various special features. This method is provided for circuit boards which are populated on both sides with SMD-components and which are to have both thermally critical and thermally uncritical THT-components. Moreover, a soldering procedure in an automatic wave soldering machine is provided here. A further special feature arises, since, in the method illustrated here, also those THT-components are considered, which are so heavy or have a tendency to tip over during transport on a circuit board, that their housing needs to be secured additionally on the circuit board by a non-conducting adhesive. This adhesive is preferably a usual adhesive, such as is also used for securing SMD-components on the circuit board.

In particular, the method illustrated in FIG. 12 matches the method shown in FIG. 11 in the first four illustrated method steps, up to the soldering 140 of the SMD-components on the first side 12 of the circuit board 10 (see, in this connection, FIGS. 1-3). Following the by now familiar turning over 130 of the circuit board 10, the method of FIG. 12 introduces an applying 148 of solder paste and non-conducting adhesive for the securing of heavy THT-components. Following the populating 144 already specified above of the second side 14 of the circuit board 10 with SMD-components, thus the setting of the SMD-components in the adhesive, comes the turning 130 of the circuit board 10 over and then a populating 150 of the first side 12 of the circuit board with thermally uncritical THT-components, which are likewise set in the adhesive and their connection pins in the connection bores 20, 30 or 40 (see FIGS. 1-3). There then follows a soldering 152 of the SMD-components on the second side 14 of the circuit board 10 and of the connection pins protruding out of this side 14 from the thermally uncritical THT-components, which themselves are held on the first side of the circuit board by the adhesive. Following this, next the already above described applying 134 of conductive adhesive onto and into the connection bores 20, 30 or 40 is performed from the second side 14 of the circuit board 10, along with—likewise from this side—an inserting 154 of the connection pins of the thermally critical THT-components. Thereafter, a curing 156 and drying of the conductive adhesive is obtained in a suitable oven. Such an oven can be, for example, a conventional drying oven; it can, however, also involve a reflow soldering oven with an appropriately selected temperature profile.

The methods shown in FIGS. 8 to 12 and described above are examples of different variants of methods of the invention for populating, securing and electrical contacting of electric and electronic components on a circuit board. Of course, other reasonable combinations of the method steps thereof may be performed. Likewise, it is possible to combine different soldering methods together and, in this way, to implement the basic ideas of the invention.

Furthermore, it has been found for all the above-described circuit boards and methods of the invention that it makes sense to use conductive adhesive not only in the case of the thermally critical THT-components but, in fact, with all THT-components used with these boards, when their connection pins, or wires, are inserted into the above-described connection bores 20, 30 and/or 40 of the invention.

1-18. (canceled)

19. A circuit board with SMD-components and a plurality of connection bores for receiving connection pins, and/or wires, of at least one wired, electric or electronic component, wherein:
said connection bores are each formed from at least two bores, which intersect such that a constriction is formed in each connection bore in an overlap region of the bores; and
said connection pins, and/or wires are securable and electrically contactable in said connection bores by a conductive adhesive.

20. The circuit board as claimed in claim 19, wherein:
the circuit board with said conductive adhesive and populated with said wired electric or electronic component is brought into an oven for drying.

21. The circuit board as claimed in claim 19, wherein:
the circuit board with said conductive adhesive and populated with said wired electric or electronic component is transported through a reflow soldering oven for the drying of said conductive adhesive during a soldering procedure for the SMD-components in such a way that the circuit board shields said wired electric or electronic component from the heat required for the soldering.

22. The circuit board with SMD-components and a plurality of connection bores for receiving connection pins, and/or wires, of at least one wired, electric or electronic component, wherein:
said connection bores are metallized and each formed from at least two bores, which intersect such that a constriction is formed in each connection bore in an overlap region of the bores; and
said connection pins, or wires, are securable in said connection bores by an adhesive and electrically contactable in the region of said constriction.

23. The circuit board as claimed in claim 22, wherein:
the circuit board with said adhesive and populated with said electric or electronic wired component inserted into said connection bores is brought into an oven for drying.

24. The circuit board as claimed in claim 22, wherein:
the circuit board with said adhesive and populated with said electric or electronic wired component is transported through a reflow soldering oven for the drying of said adhesive during a soldering procedure for the SMD-components in such a way that the circuit board shields said wired electric or electronic component from the heat required for the soldering.

25. The circuit board as claimed in claim 19, wherein:
said bores forming a connection bore are oppositely directed, blind bores.

26. The circuit board as claimed in claim 19, wherein:
said connection bores are parallel, traversing bores.

27. The method for populating, securing and electrical contacting of electric and electronic components on a circuit board, comprising the steps of:
producing in the circuit board a plurality of connection bores for receiving connection pins, and/or wires, of at least one wired, electric or electronic component each from at least two bores, which intersect such that a constriction is formed in each connection bore in an overlap region of the bores;
applying solder paste on solder pads and conductive adhesive on and/or into the connection bore for the wired, electric or electronic component on one side of the circuit board;
populating SMD-components onto the soldering pads and inserting the connection pins, or wires, of the wired component into the connection bore; and
soldering the solder paste and drying the conductive adhesive in a reflow soldering oven.

28. The method as claimed in claim 27, wherein:
a thermally critical, wired component is populated on the side of the circuit board lying opposite to the SMD-components, before the completely populated circuit board is charged into the reflow soldering oven; and
the circuit board shields the wired component during passage through the reflow soldering oven from the heat required for the soldering.

29. The method for the two-sided populating, securing and electrical contacting of electric and electronic components on a circuit board, comprising the steps of:
producing in the circuit board a plurality of connection bores for receiving connection pins, and/or wires, of at least one wired, electric or electronic component each from at least two bores, which intersect such that a constriction is formed in each connection bore in an overlap region of the bores;
applying conductive adhesive on and/or into the connection bore for the wired electric or electronic component on a second side of the circuit board;
inserting the connection pins, or wires, of the wired component into the connection bores;
applying solder paste on solder pads on a first side of the circuit board;
populating SMD-components on the solder pads of the first side of the circuit board; and
soldering the solder paste and drying the conductive adhesive in a reflow soldering oven, wherein the circuit board shields the wired component during passage through the reflow soldering oven from the heat required for the soldering.

30. The method for the two-sided populating, securing and electrical contacting of electric or electronic components on a circuit board, comprising the steps of:
producing in the circuit board a plurality of connection bores for receiving connection pins, and/or wires, of at least one wired, electric or electronic component each from at least two bores, which intersect such that a constriction is formed in each connection bore in an overlap region of the bores;
applying solder paste on solder pads on a first side of the circuit board;
populating SMD-components on the solder pads on the first side of the circuit board;
soldering the first side of the circuit board in a reflow soldering oven;
applying solder paste on solder pads and applying conductive adhesive on and/or into the connection bore for the wired, electric or electronic component on a second side of the circuit board;
inserting the connection pins, or wires, of the wired component into the connection bore;
populating SMD-components on the solder pads of the second side of the circuit board; and
soldering the solder paste and drying the conductive adhesive in a reflow soldering oven.

31. The method as claimed in claim 30, wherein:
in the case of a thermally critical, wired component, the connection pins, or wires, of the wired component are inserted into the connection bores from the first side of the circuit board following the application of conductive adhesive on the second side of the circuit board; and
the circuit board shields the wired component during the passage through the reflow soldering oven from the heat required for the soldering.

32. A method for the two-sided populating, securing and electrical contacting of electric or electronic components on a circuit board, comprising the steps of:
producing in the circuit board a plurality of connection bores for receiving connection pins, and/or wires, of at least one wired, electric or electronic component each from at least two bores, which intersect such that a constriction is formed in each connection bore in an overlap region of the bores;
applying solder paste on solder pads on a first side of the circuit board;
populating SMD-components on the solder pads;
soldering the solder paste and the SMD-components on the first side of the circuit board in a reflow soldering oven;
inserting the connection pins, or wires, of the wired component into the connection bore;
applying solder paste on solder pads and applying conductive adhesive on and/or into the connection bore for the wired, electric or electronic component on a second side of the circuit board;
populating SMD-components on the solder pads of the second side of the circuit board; and
soldering the solder paste and the SMD-components of the second side of the circuit board and drying the conductive adhesive in a reflow soldering oven, wherein the circuit board shields the wired component during passage through the reflow soldering oven from the heat required for the soldering.

33. A method for the two-sided populating, securing and electrical contacting of SMD-components and a plurality of wired components, of which at least one is a thermally critical, wired component, on a circuit board, comprising the steps of:
producing in the circuit board a plurality of connection bores for receiving connection pins, and/or wires, of at least one wired, electric or electronic component each from at least two bores, which intersect such that a constriction is formed in each connection bore in an overlap region of the bores;
applying solder paste on solder pads on a first side of the circuit board;
populating SMD-components on the solder pads;
soldering the first side of the circuit board in a reflow soldering oven;
applying adhesive onto a second side of the solder board for securing SMD-components;
populating the second side of the circuit board with SMD-components;
populating the one or more wired and thermally uncritical components on the first side of the circuit board;
soldering in a wave soldering facility;
applying conductive adhesive onto and/or into the connection bore for the wired, electric or electronic component on the second side of the circuit board;
inserting the connection pins, or wires, of the thermally critical, wired component into the connection bore; and
curing the conductive adhesive.

34. The method as claimed in claim 27, wherein:
in the case of applying a plurality of wired components on the circuit board, all wired components are inserted in connection bores and secured by conductive adhesive.

35. The method as claimed in claim 27, wherein:
the connection bores for receiving connection pins, or wires, of the wired components are metallized.

36. The method as claimed in claim 27, wherein:
connection bores for receiving connection pins, or wires, of the wired components are metallized and, in place of the conductive adhesive, a non-conducting adhesive is used; and
an electrical contacting of the connection pins, or wires, of the wired components is produced in the area of the constrictions of the connection bores.
